(19) United States
(12) Patent Application Publication
(10) Pub. No.: US 2019/0320532 A1
(43) Pub. Date: Oct. 17, 2019

(54) MODULAR CIRCUIT BOARD

(71) Applicants: Tri-Net Electronics Co., Ltd., Taipei (TW); Dongguan three net Electronic Technoogy Co., Ltd., Dongguan (CN)

(72) Inventors: FUNG-CHIH CHOU, Taipei (TW); SHENG-HUI TSENG, Taipei (TW); WEN-YUAN LIN, Taipei (TW)

(21) Appl. No.: 16/115,574

(22) Filed: Dec. 10, 2018

(30) Foreign Application Priority Data
Apr. 17, 2018 (TW) 107204984

(51) Int. Cl. H05K 1/14; H05K 5/00; H05K 5/02; H01R 12/71

(52) U.S. Cl. CPC H05K 1/144; H05K 5/0047; H05K 5/0247; H01R 12/716; H05K 5/03; H05K 2201/10356; H05K 2201/10409; H05K 2201/042; H05K 2201/10303

(57) ABSTRACT

A modular circuit board that can quickly replace and assemble a port, comprises a first circuit board, at least one second circuit board connected to the first circuit board, at least one connecting post disposed between the first and second circuit boards, and at least one connecting component electrically connected to the first circuit board and the second circuit board; if the modular circuit board needs to replace different ports, it is only need to disassemble the connection post and replace the second circuit board of the second signal port, which not only can reduce the cost of production, and replacement and assembly is more convenient.

### BACKGROUND OF INVENTION

### 1. Field of the Invention

The invention relates to the technical field of a circuit board, in particular to a modular circuit board capable of quickly replacing and assembling a connection port.

### 2. Description of Related Art

At present, the connection port is electrically connected to the circuit board separately. However, since the size of the electronic device is now miniaturized, the size of the circuit board is also reduced, Therefore, if you want to make a variety of different ports on the circuit board, it is bound to be limited by the space of the board. Moreover, the connection ports of various specifications are soldered on the circuit board, so that the manufacturing should take a longer time, and since the soldering method is used, the specifications of the circuit board are fixed, if one user want to add another connection port, such as VGA, HDMI, DVI, USB, Type C, or Display Port, the manufacturer has to redesign and manufacture the circuit board, which is relatively time consuming, resulting in increased production costs.

In view of the above, how to improve the above problems and develop a modular circuit board that can quickly replace and assemble the port is a major subject of the present invention.

### SUMMARY OF THE INVENTION

It is an object of the present invention to provide a modular circuit board that can be quickly replaced and assembled.

The technical solution of the present invention is to provide a modular circuit board, the modular circuit board comprising a first circuit board including a plurality of electronic components, a circuit layout, at least a first signal port and a power port respectively connected to a signal circuit and a power circuit disposed on the first circuit board, and at least one first through hole disposed on a surface of the first circuit board;

at least one second circuit board connected to the first circuit board, and including a plurality of electronic components, a circuit layout, a signal circuit connected to at least one second signal port, and a second through hole disposed on a surface of the second circuit board and corresponding to the first through hole;

at least one connecting post disposed between the first and second circuit boards, and one end thereof is fixed to the first through hole, and another end thereof is fixed to the second hole, such that the first and second circuit boards are detachably coupled; and,

at least one connecting component electrically connected to the first circuit board and the second circuit board.

More particularly, wherein the connecting post is one of the following: a copper post, an iron post, and a plastic post.

More particularly, wherein the connecting component is one of the following: a header pin and a flat flexible cable.

More particularly, wherein the first connection signal port is an HDMI signal port or a Fiber signal port.

More particularly, wherein the second signal port is one of the following: an HDMI port, a VGA port, a Component port, a Type C port, a DVI port, a Display Port, a Fiber port, an USB port, a Bluetooth, a WI-FI.

More particularly, wherein the first circuit board further includes at least one network port connected to the signal circuit and the power circuit.

More particularly, wherein the modular circuit board further includes a console; the console is electrically connected to the first circuit board (1) by a flexible cable.

More particularly, wherein the modular circuit board further includes a housing having a space for receiving the first and second circuit board and the console, and a plurality of through holes disposed on a surface thereof.

More particularly, wherein the modular circuit board further includes a sleeve that is sleeved on the connecting component of the first circuit board, and four sides of an inner portion of the sleeve respectively have a slope, so that the first and second circuit boards can be smoothly and quickly connected.

According to the above, the present invention can achieve the following effects:

If it is necessary to replace the port of different specifications, it is only necessary to disassemble the connection post (3) and replace the second circuit board (2) of the second signal port (21), so that the manufacturer can change variously specifications of the port according to his needs, such as HDMI port, VGA port, Component port, Type C port, DVI port, Display Port, Fiber port, USB port, etc., as well as Bluetooth, WiFi, to match the use of different electronic devices, not only can reduce the cost of production, and replacement and assembly is more convenient.

### BRIEF DESCRIPTION OF THE DRAWINGS

FIG. 1 is a perspective view of the present invention;

FIG. 2 is an exploded perspective view of the present invention;

FIG. 3 is a perspective view of in combination with a housing;

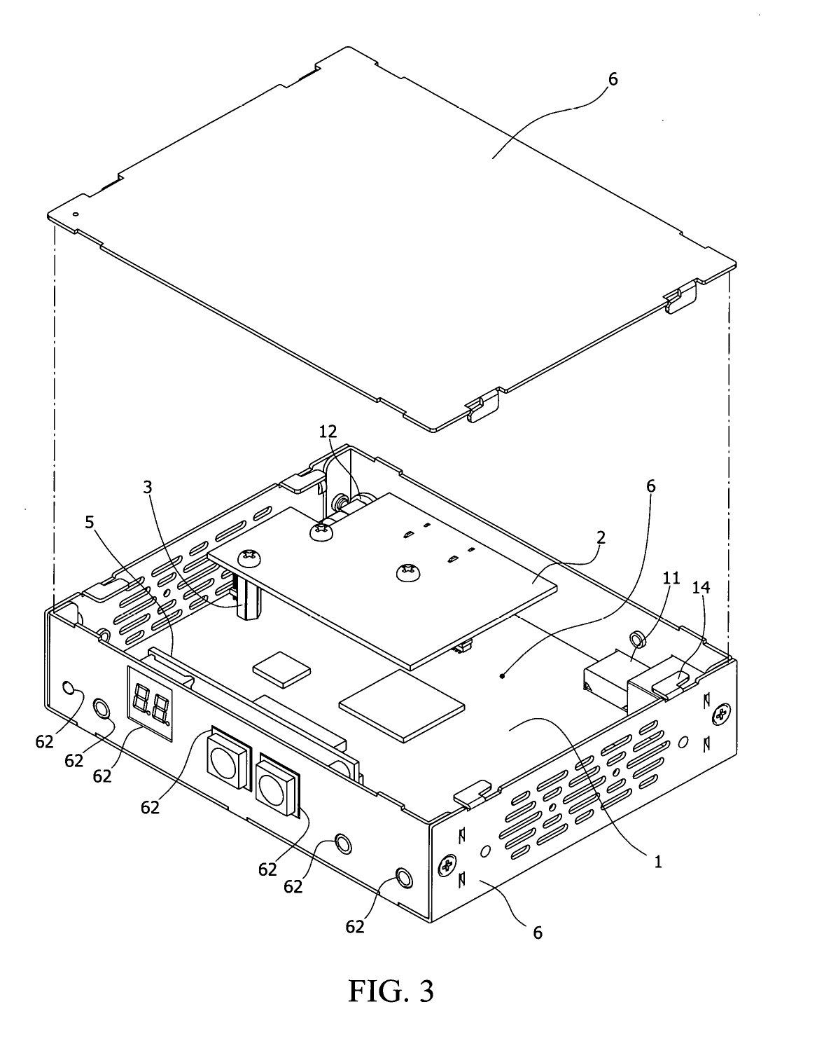

FIG. 4 is a schematic view showing the implementation of the collocation network in combination the present invention;

FIG. 5 is a perspective view the present invention having sleeves disposed thereon;

FIG. 6 is an exploded perspective view the present invention having the sleeves.

### DETAILED DESCRIPTION OF THE INVENTION

The invention will now be further described with reference to the embodiments and the drawings.

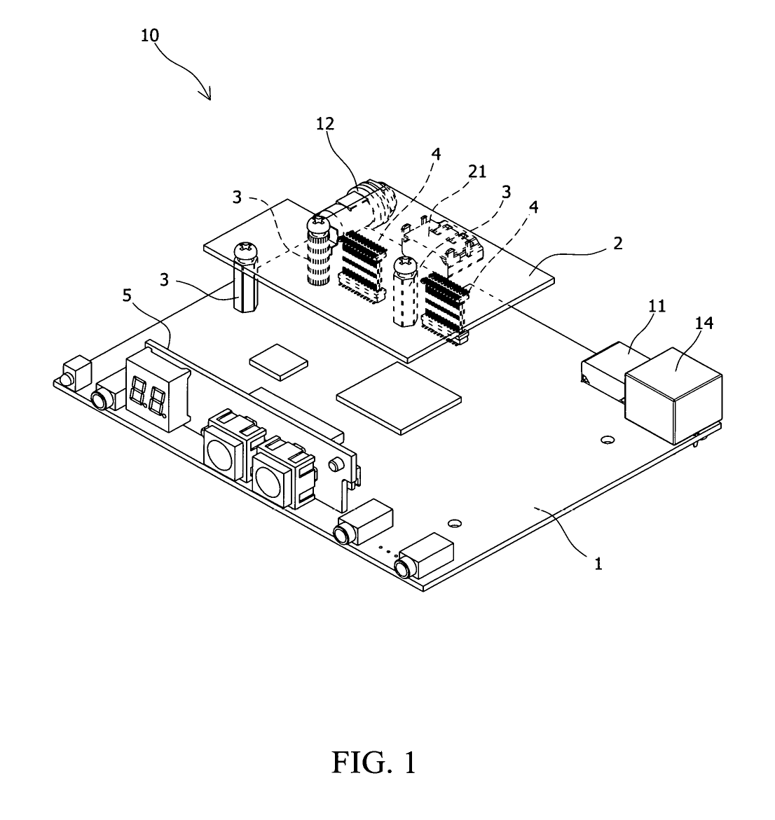

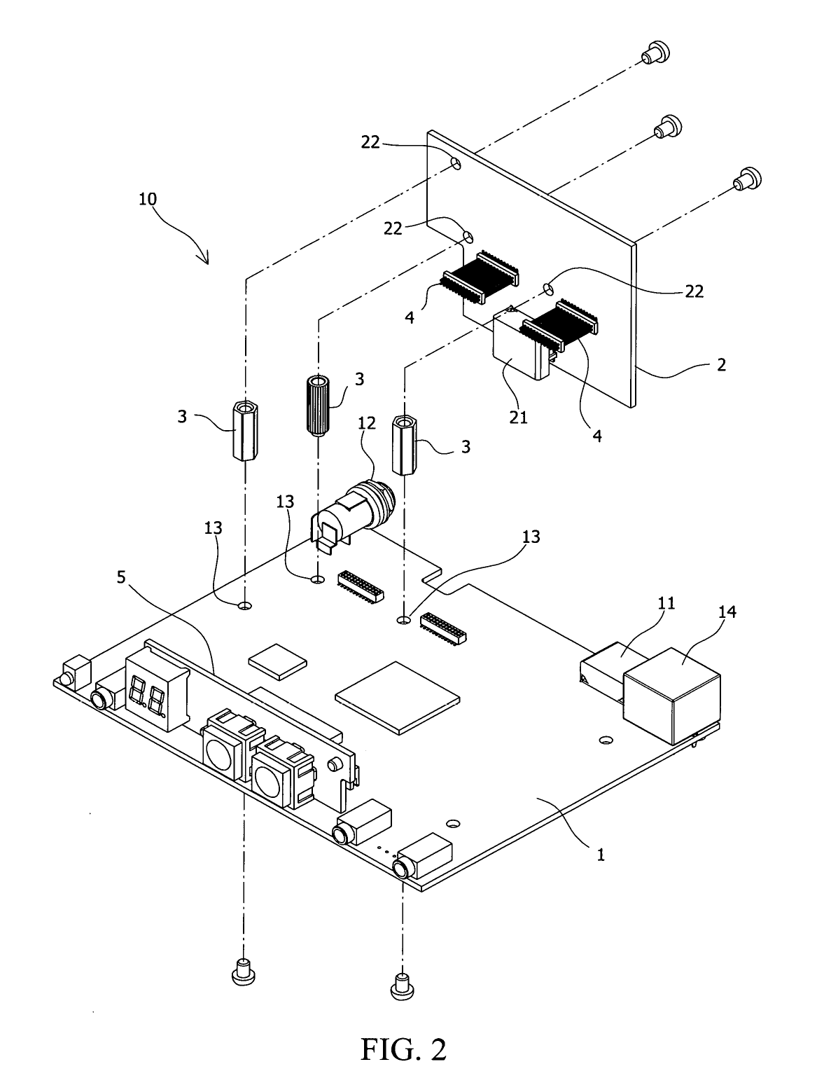

As shown in FIGS. 1 and 2, the FIGs disclose a modular circuit board 10, comprising a first circuit board (1) including a plurality of electronic components, a circuit layout, at least a first signal port (11) and a power port (12) respectively connected to a signal circuit and a power circuit disposed on the first circuit board (1), and at least one first through hole (13) disposed on a surface of the first circuit board (1); at least one second circuit board (2) connected to the first circuit board (1), and including a plurality of electronic components, a circuit layout, a signal circuit connected to at least one second signal port (21), and a second through hole (22) disposed on a surface of the second circuit board (2) and corresponding to the first through hole (13); at least one connecting post (3) disposed between the first and second circuit boards (1, 2), and one end thereof is fixed to the first through hole (13), and another end thereof is fixed to the second hole (22), such that the first and second circuit boards (1, 2) are detachably coupled; and, at least one connecting component (4) electrically connected to the first circuit board (1) and the second circuit board (2).

The first and second circuit boards (1, 2) arc connected by the connecting post (3), so that the upper and lower ends of the connecting post (3) can be used by locking the first and second circuit boards (1, 2), as compared with the traditional soldering connection, the configuration of the connecting post (3) can greatly improve the convenience of use, and reduce the time and cost of production. Furthermore, if it needs to replace ports, it only needs to disassemble the connection post (3) and replace the second circuit board (2) of the second signal port (21), so that the manufacturer can change variously specifications of the port according to his needs, such as HDMI port, VGA port, Component port, Type C port, DVI port, Display Port, Fiber port, USB port, etc., as well as Bluetooth, WiFi, to match the use of different electronic devices, not only can reduce the cost of production, and replacement and assembly is more convenient. In addition, the connecting post (3) is made of copper, iron or plastic, as long as the purpose of the creation and the function of the connecting post of the present invention are equal, the changed or modified design is within the scope of the present invention.

Secondly, the first and second circuit boards (1, 2) can be electrically connected by a pin or a flexible cable.

As shown in FIGS. 1 and 2, the first signal port (11) is an HDMI signal port, and the second signal port (21) is one of the following: an HDMI port, a VGA port, a Component port, a Type C port, a DVI port, and a Display Port, Fiber port, USB port, Bluetooth, WI-FI.

When the signal input by the second signal port 21 is output, the signal flows through the HDMI signal conversion chip on the first circuit board (1) for conversion, and then the converted HDMI signal is transmitted to the first signal port (11) and output to an electronic device for display ; thus, the modular circuit board (10) can be used with a variety of different specifications of the port, and the signals output by the ports can be converted into HDMI signals for use in different electronic devices.

Wherein the modular circuit board (10) further includes a console (5); the console (5) is electrically connected to the first circuit board (1) by a flexible cable; the modular circuit board (10) further includes a housing (6) having a space (61) for receiving the first and second circuit board (1, 2) and the console. Accordingly, the first and second circuit boards (1, 2) and the console (5) can be covered by the housing (6) for protection and dust prevention. In addition, the modular circuit board (10) further includes a plurality of through holes (62) disposed on a surface thereof and conFIG.d for the buttons on the console (5), the power port (12) on the first and second circuit boards (1, 2), and the first and second signal ports (11, 12) inserted therein.

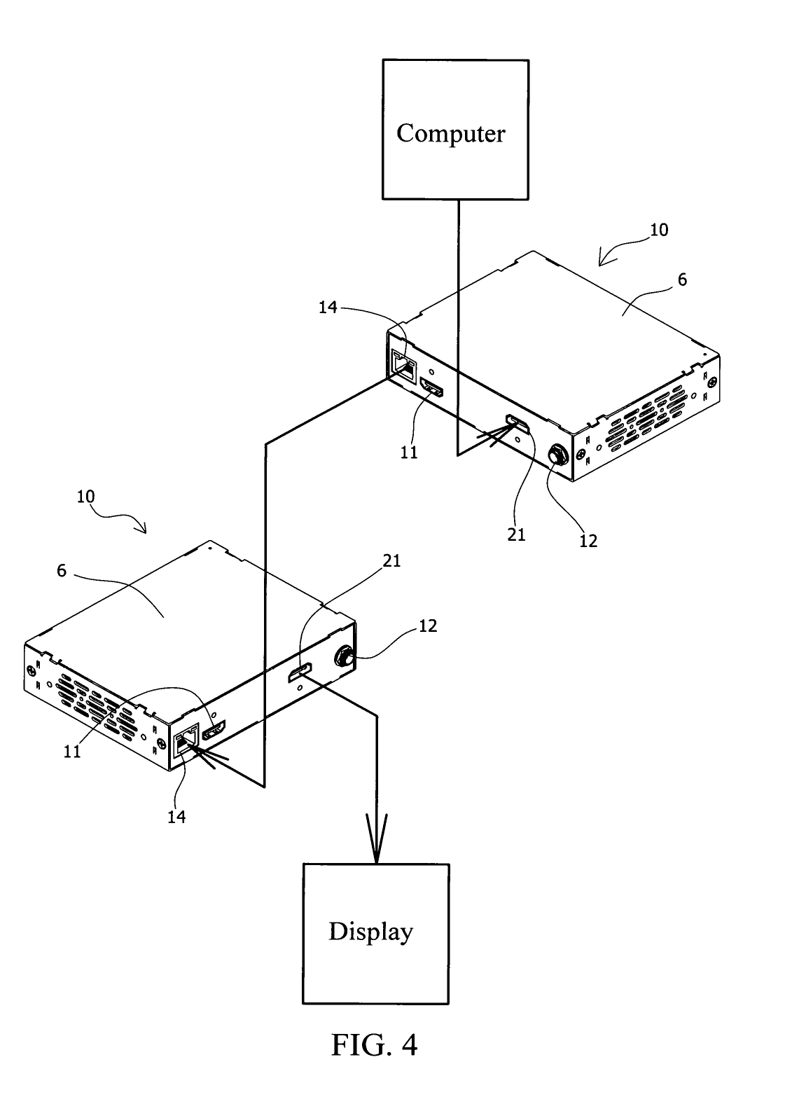

As shown in FIG. 4, the first circuit board (1) further includes at least one network port (14) connected to the signal circuit and the power circuit; the network port includes an RJ45 port and a Fiber port.

The modular circuit board (10) is connected to another modular circuit board 10 by a network route or Fiber or Bluetooth or WiFi through the network plug connector 14, so that the HDMI signal can be transmitted to the modular circuit board (10) by the network signal to provide the other modular circuit board (10) for image, sound, signal transmission and the like.

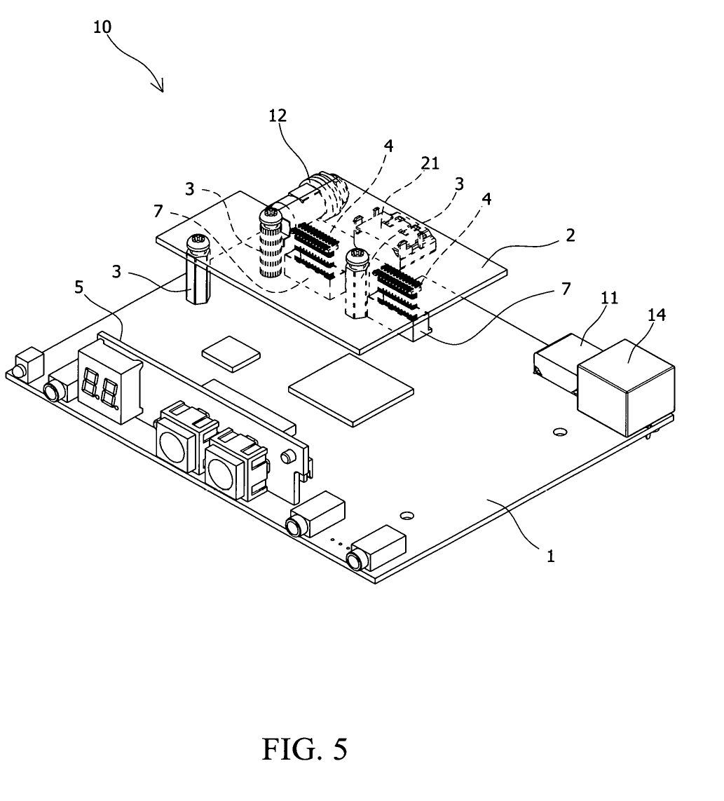

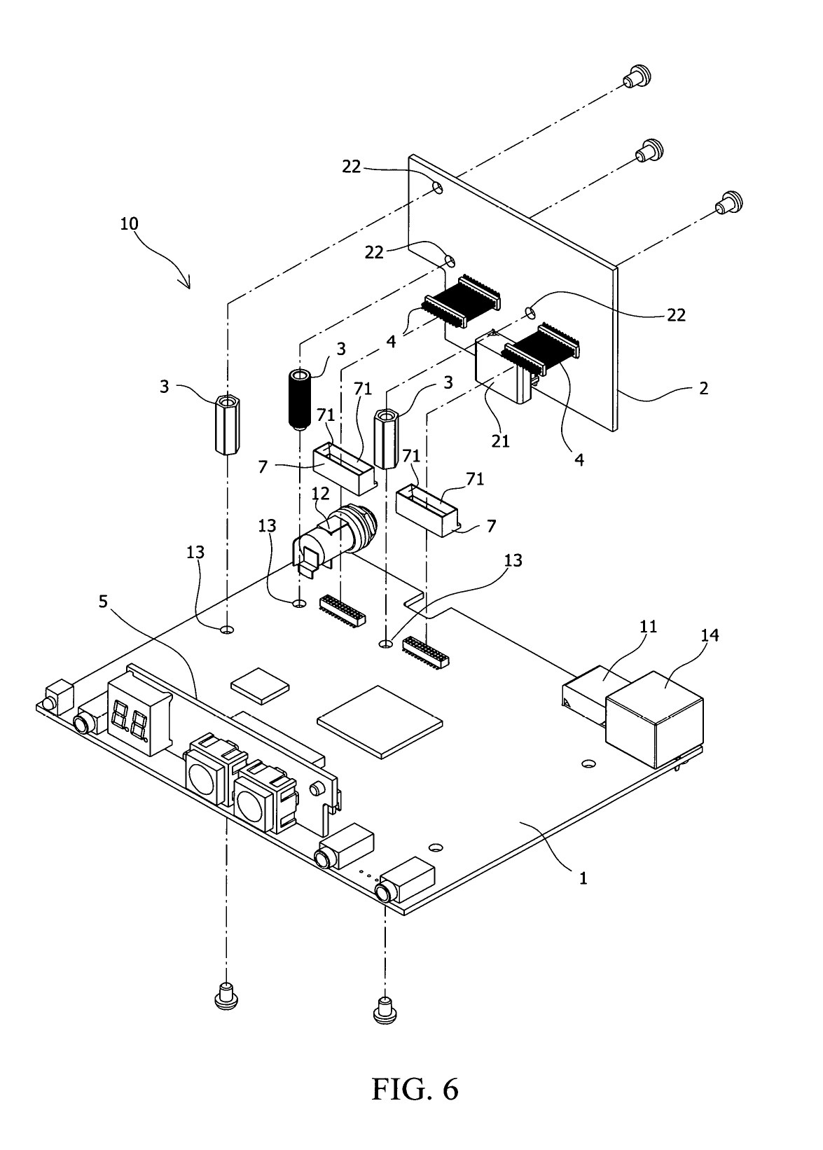

As shown in FIGS. 5 and 6, the modular circuit board (10) further includes a sleeve (7) that is sleeved on the connecting component (4) of the first circuit board (1), and four sides of an inner portion of the sleeve (7) respectively have a slope (71), so that the first and second circuit boards (1, 2) can be smoothly and quickly connected.

The above only describes some exemplary embodiments of the present invention. Those having ordinary skills in the art may also make many modifications and improvements without departing from the conception of the invention, which shall all fall within the protection scope of the invention.

I claim:

1. A modular circuit board, the modular circuit board (10) comprising:
a first circuit board (1) including a plurality of electronic components, a circuit layout, at least a first signal port (11) and a power port (12) respectively connected to a signal circuit and a power circuit disposed on the first circuit board (1), and at least one first through hole (13) disposed on a surface of the first circuit board (1);
at least one second circuit board (2) connected to the first circuit board (1), and including a plurality of electronic components, a circuit layout, a signal circuit connected to at least one second signal port (21), and a second through hole (22) disposed on a surface of the second circuit board (2) and corresponding to the first through hole (13);
at least one connecting post (3) disposed between the first and second circuit boards (1, 2), and one end thereof is fixed to the first through hole (13), and another end thereof is fixed to the second hole (22), such that the first and second circuit boards (1, 2) are detachably coupled; and,
at least one connecting component (4) electrically connected to the first circuit board (1) and the second circuit board (2).

2. The modular circuit board according to claim 1, wherein the connecting post (3) is one of the following: a copper post, an iron post, and a plastic post.

3. The modular circuit board according to claim 1, wherein the connecting component (4) is one of the following: a header pin and a flat flexible cable.

4. The modular circuit board according to claim 1, wherein the first connection signal port (11) is an HDMI signal port or a Fiber signal port.

5. The modular circuit board according to claim 1, wherein the second signal port (21) is one of the following: an HDMI port, a VGA port, a Component port, a Type C port, a DVI port, a Display Port, a Fiber port, an USB port, a Bluetooth, a WI-FI.

6. The modular circuit board according to claim 1, wherein the first circuit board (1) further includes at least one network port (14) connected to the signal circuit and the power circuit.

7. The modular circuit board according to claim 1, wherein the modular circuit board (10) further includes a console (5); the console (5) is electrically connected to the first circuit board (1) by a flexible cable.

8. The modular circuit board according to claim 7, wherein the modular circuit board (10) further includes a housing (6) having a space (61) for receiving the first and second circuit board (1, 2) and the console, and a plurality of through holes (62) disposed on a surface thereof.

9. The modular circuit board according to claim 1, wherein the modular circuit board (10) further includes a sleeve (7) that is sleeved on the connecting component (4) of the first circuit board (1), and four sides of an inner portion of the sleeve (7) respectively have a slope (71), so that the first and second circuit boards (1, 2) can be smoothly and quickly connected.
